(19) United States
(12) Patent Application Publication
(10) Pub. No.: US 2025/0079424 A1
(43) Pub. Date: Mar. 6, 2025

(54) SEMICONDUCTOR PACKAGE AND METHOD OF MANUFACTURING THE SAME

(71) Applicant: Samsung Electronics Co., Ltd., Suwon-si (KR)

(72) Inventors: Hyunsoo Chung, Suwon-si (KR); Kwangsoo Kim, Suwon-si (KR); Chiwoo Lee, Suwon-si (KR)

(21) Appl. No.: 18/757,933

(22) Filed: Jun. 28, 2024

(30) Foreign Application Priority Data
Aug. 29, 2023 (KR) 10-2023-0113969

(51) Int. Cl. H01L 25/16; G02B 6/42; H01L 23/00; H01L 23/31; H01L 23/48

(52) U.S. Cl. CPC H01L 25/167; G02B 6/4243; H01L 23/3135; H01L 23/481; H01L 24/08; H01L 24/16; H01L 24/32; H01L 24/73; H01L 2224/08145; H01L 2224/16145; H01L 2224/16225; H01L 2224/32145; H01L 2224/73253; H01L 2924/1436

(57) ABSTRACT

A semiconductor package includes a redistribution layer, a photonic integrated circuit (PIC) chip on the redistribution layer, a buffer chip on the redistribution layer, an electronic integrated circuit (EIC) chip on the PIC chip and the buffer chip, and a plurality of stacked structures on the buffer chip, each of the plurality of stacked structures including a plurality of stacked semiconductor chips. The plurality of stacked structures are spaced apart from one another in a horizontal direction, and a portion of the EIC chip overlaps the PIC chip in a vertical direction, and another portion of the EIC chip overlaps the buffer chip in a vertical direction.

### CROSS-REFERENCE TO RELATED APPLICATION

This application is based on and claims priority under 35 U.S.C. § 119 to Korean Patent Application No. 10-2023-0113969, filed on Aug. 29, 2023, in the Korean Intellectual Property Office, the disclosure of which is incorporated by reference herein in its entirety.

### BACKGROUND

The inventive concept relates to a semiconductor package and a method of manufacturing the same, and more particularly, to a semiconductor package including a photonic integrated circuit (PIC) chip and a method of manufacturing the same.

Advantages of semiconductor packages are increasingly being utilized to improve functionality of electronic devices and integrate components. A semiconductor package may allow various integrated circuits, such as memory chips or logic chips, to be mounted on a package substrate. Recently, in an environment in which data traffic is increasing in data centers and communication infrastructure, research on semiconductor packages including PIC chips is continuously performed.

### SUMMARY

The inventive concept relates to a semiconductor package that may have improved power efficiency and a method of manufacturing the same.

The inventive concept relates to a semiconductor package that may have an increased data processing speed and increased memory capacity and a method of manufacturing the same.

In addition, the problems to be solved by the technical idea of the inventive concept are not limited to the above-mentioned problems, and other problems not mentioned will be clearly understood by those skilled in the art from the following description.

According to an aspect of the inventive concept, a semiconductor package includes a redistribution layer, a photonic integrated circuit (PIC) chip on the redistribution layer, a buffer chip on the redistribution layer, an electronic integrated circuit (EIC) chip on the PIC chip and the buffer chip, and a plurality of stacked structures on the buffer chip, each of the plurality of stacked structures including a plurality of stacked semiconductor chips. The plurality of stacked structures are spaced apart from one another in a horizontal direction, and a portion of the EIC chip overlaps the PIC chip in a vertical direction, and another portion of the EIC chip overlaps the buffer chip in a vertical direction.

According to another aspect of the inventive concept, a semiconductor package includes a redistribution layer, a photonic integrated circuit (PIC) chip on the redistribution layer and configured to convert an optical signal into an electrical signal, a buffer chip on the redistribution layer and spaced apart from the PIC chip in a horizontal direction, an electronic integrated circuit (EIC) chip above the PIC chip and the buffer chip, and having one end portion positioned above the PIC chip and the other end portion positioned above the buffer chip in a first horizontal direction, a plurality of stacked structures on the buffer chip, each of the plurality of stacked structures including a plurality of stacked semiconductor chips, and a molding layer on a top surface of the redistribution layer and side surfaces of the PIC chip, the buffer chip, the EIC chip, and the plurality of stacked structures. A plurality of stacked structures are spaced apart from one another in a horizontal direction.

According to another aspect of the inventive concept, a semiconductor package includes a redistribution layer, a photonic integrated circuit (PIC) chip on the redistribution layer and including an optical-to-electric conversion unit, a buffer chip on the redistribution layer and spaced apart from the PIC chip in a horizontal direction, an electronic integrated circuit (EIC) chip on the PIC chip and the buffer chip and positioned to overlap the PIC chip and the buffer chip, a plurality of stacked structures on the buffer chip, each of the plurality of stacked structures including a plurality of stacked semiconductor chips, and being spaced apart from one another in a horizontal direction, an optical fiber positioned above the optical-to-electric conversion unit of the PIC chip, and a molding layer on a top surface of the redistribution layer and side surfaces of the PIC chip, the buffer chip, the EIC chip, and the plurality of stacked structures.

### BRIEF DESCRIPTION OF THE DRAWINGS

Embodiments will be more clearly understood from the following detailed description taken in conjunction with the accompanying drawings in which:

FIG. 1 is a plan view schematically illustrating a semiconductor package according to some embodiments;

FIG. 2 is a cross-sectional view schematically illustrating the semiconductor package of FIG. 1 taken along the line A-A′ of FIG. 1;

FIG. 3 is a cross-sectional view schematically illustrating the semiconductor package of FIG. 1 by enlarging the portion “EX1” of FIG. 1;

FIG. 4 is a cross-sectional view schematically illustrating the semiconductor package of FIG. 1 by enlarging the portion “EX2” of FIG. 1;

FIGS. 5 to 8 are cross-sectional views schematically illustrating a semiconductor package taken along the line A-A′ of FIG. 1 according to some embodiments;

FIGS. 9 to 11 are plan views schematically illustrating semiconductor packages according to some embodiments; and

FIGS. 12 to 18 are views illustrating a method of manufacturing a semiconductor package according to some embodiments.

### DETAILED DESCRIPTION OF THE EMBODIMENTS

Because the current embodiments may be subject to various changes and have various forms, some embodiments will be illustrated in the drawings and described in detail. However, the current embodiments are not limited to a specific disclosure form.

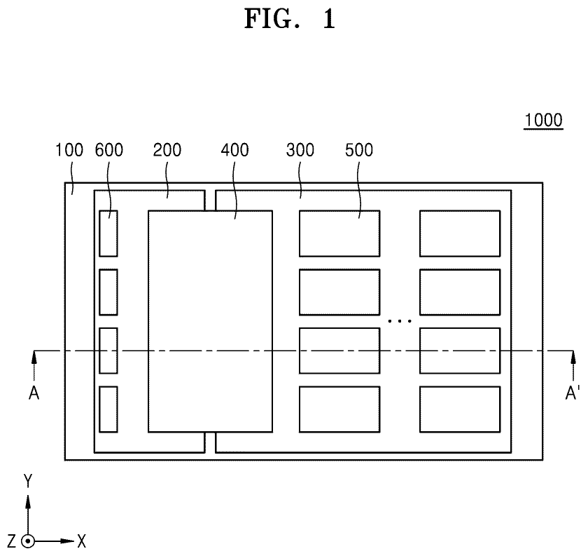

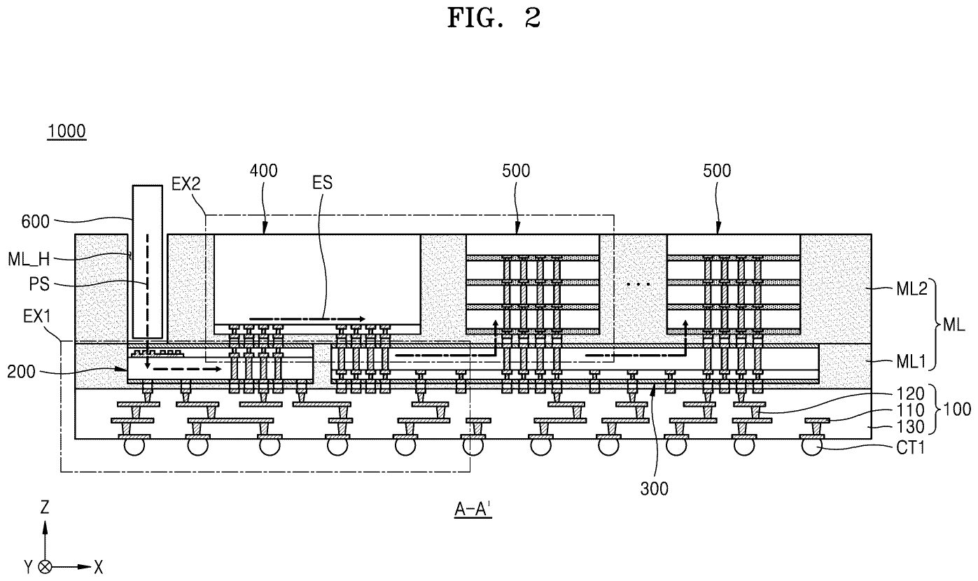

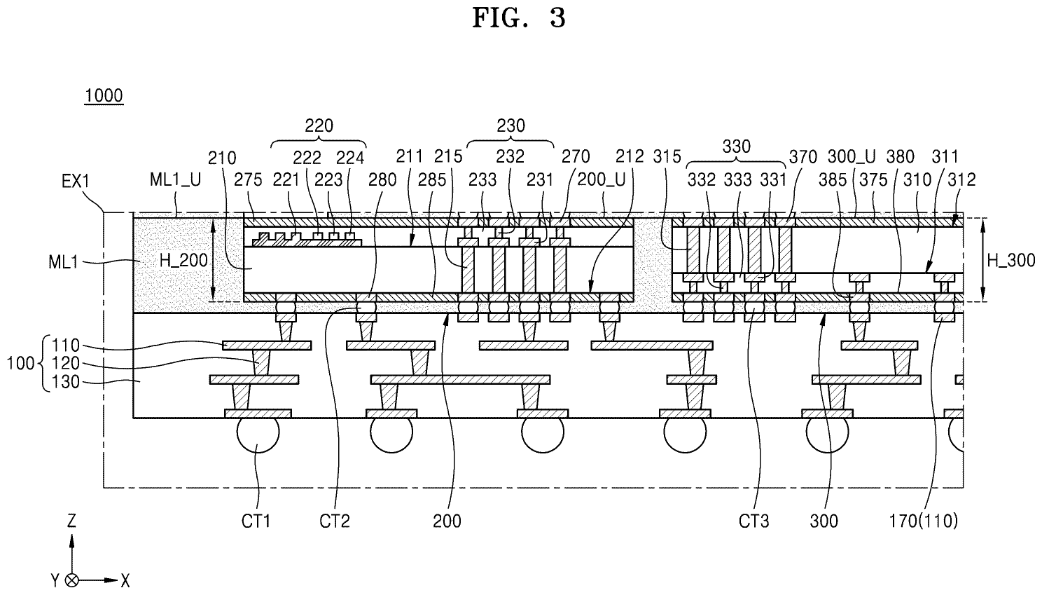

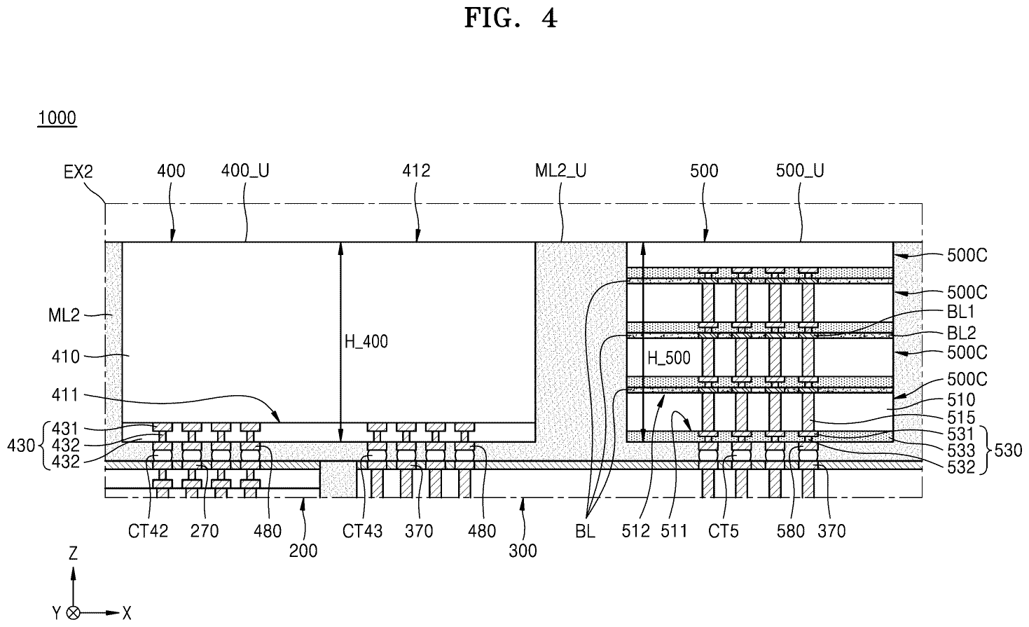

FIG. 1 is a plan view schematically illustrating a semiconductor package 1000 according to some embodiments. FIG. 2 is a cross-sectional view schematically illustrating the semiconductor package 1000 of FIG. 1 taken along the line A-A′ of FIG. 1. FIG. 3 is a cross-sectional view schematically illustrating the semiconductor package 1000 of FIG. 1 by enlarging the portion “EX1” of FIG. 2. FIG. 4 is a cross-sectional view schematically illustrating the semiconductor package 1000 of FIG. 1 by enlarging the portion “EX2” of FIG. 2.

Referring to FIGS. 1 to 4, the semiconductor package 1000 may include a redistribution layer 100, a photonic integrated circuit (PIC) chip 200, a buffer chip 300, an electronic integrated circuit (EIC) chip 400, and a plurality of stacked structures 500. In some embodiments, the semiconductor package 1000 may further include a molding layer ML and an optical fiber 600.

The semiconductor package 1000 may convert an input optical signal PS into an electrical signal ES and may convert the electrical signal ES into an optical signal PS to output the optical signal PS. In FIG. 2, dashed arrows indicate paths through which the optical signal PS moves, and dash-single dotted arrows indicate paths through which the electrical signal ES moves. In FIG. 2, the dotted arrows and the dashed-dotted arrows indicate a process of inputting the optical signal PS into the semiconductor package 1000. However, the dotted arrows and the dashed-dotted arrows may progress in a reverse direction so that the optical signal PS may be output from the semiconductor package 1000.

Hereinafter, unless specifically defined, a direction parallel to a top surface of the redistribution layer 100 is defined as a first horizontal direction (X direction), a direction perpendicular to the top surface of the redistribution layer 100 is defined as a vertical direction (Z direction), and a direction perpendicular to the first horizontal direction (X direction) and the vertical direction (Z direction) is defined as a second horizontal direction (Y direction).

The redistribution layer 100 of the semiconductor package 1000 may include wiring lines 110, vertical vias 120 vertically connecting the wiring lines 110 to one another, and an insulating layer 130 on or surrounding the wiring lines 110 and the vertical vias 120. Among the wiring lines 110, the wiring lines 110 that are exposed or free from the top surface of the redistribution layer 100 may be referred to as upper pads 170.

In some embodiments, structurally, each of the vertical vias 120 in the redistribution layer 100 may have a width in the first horizontal direction (X direction) and/or a width in the second horizontal direction (Y direction) gradually increasing toward a bottom surface of the PIC chip 200. That is, a horizontal area of each of the vertical vias 120 of the redistribution layer 100 may increase toward a top surface of the redistribution layer 100. For example, the semiconductor package 1000 may be manufactured in a chip-last method.

In some embodiments, for example, the vertical vias 120 and the wiring lines 110 may include a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy thereof.

In some embodiments, the redistribution layer 100 may include an interposer. For example, the redistribution layer 100 may be formed on a silicon substrate including a through silicon via (TSV). Accordingly, the redistribution layer 100 may include a portion of the interposer. For example, the redistribution layer 100 may be referred to as an interposer or a package substrate.

External connection terminals CT1 may be provided on a bottom surface of the redistribution layer 100. The external connection terminals CT1 may be attached to the vertical vias 120 or the wiring lines 110 of the redistribution layer 100. The external connection terminals CT1 may electrically and physically connect the redistribution layer 100 to an external device on which the redistribution layer 100 is mounted. The external connection terminals CT1 may include, for example, solder balls or solder bumps.

The PIC chip 200 and the buffer chip 300 will be described in detail with reference to FIG. 3.

The PIC chip 200 of the semiconductor package 1000 may input and output the optical signal PS. Specifically, the PIC chip 200 may convert the electrical signal ES into the optical signal PS to transmit the optical signal PS to the optical fiber 600 and may convert the optical signal PS received from the optical fiber 600 into the electrical signal ES to transmit the electrical signal ES to the EIC chip 400.

The PIC chip 200 may include a first substrate 210, a first wiring structure 230, an optical-to-electric conversion unit 220, and first through vias 215.

The first substrate 210 may include an active surface 211 on which a plurality of individual elements are formed, and an inactive surface 212 opposite the active surface 211. The first wiring structure 230 may be formed on the active surface 211 of the first substrate 210. The first through vias 215 may extend from the inactive surface 212 of the first substrate 210 to the active surface 211 thereof. In some embodiments, the first through vias 215 may be electrically connected to the first wiring structure 230 and/or the plurality of individual elements on the active surface 211 of the first substrate 210.

The PIC chip 200 may be on the redistribution layer 100 so that the active surface 211 of the first substrate 210 of the PIC chip 200 faces the EIC chip 400. For example, the PIC chip 200 may be on the redistribution layer 100 in a face-up manner. In the current specification, the active surface 211 of the first substrate 210 may be referred to as a top surface of the first substrate 210, and the inactive surface 212 of the first substrate 210 may be referred to as a bottom surface of the first substrate 210. However, a relationship between the active surface 211 and the inactive surface 212 is not limited thereto.

The first substrate 210 may include a semiconductor material such as silicon (Si). Alternatively, the first substrate 210 may include a semiconductor material such as germanium (Ge).

The optical-to-electric conversion unit 220 of the PIC chip 200 may convert the optical signal PS into the electrical signal ES and the electrical signal ES into the optical signal PS. In some embodiments, the optical-to-electric conversion unit 220 may include a grating coupler 221, a photodetector 222, a laser diode 223, and a modulator 224.

The grating coupler 221 may include a path through which the optical signal PS input through the optical fiber 600 moves to the photodetector 222, and/or a path through which the optical signal PS emitted from the laser diode 223 is output to the optical fiber 600. For example, the grating coupler 221 may provide a path through which the optical signal PS moves in a horizontal direction on the top surface of the first substrate 210.

While the optical signal PS is input to the PIC chip 200, the photodetector 222 may detect the optical signal PS input to the PIC chip 200. The optical signal PS may be detected by the photodetector 222 to be converted into the electrical signal ES. The electrical signal ES converted by the photodetector 222 may be transmitted to the plurality of individual elements on the active surface 211 of the first substrate 210 of the PIC chip 200.

While the PIC chip 200 outputs the optical signal PS, the plurality of individual elements on the active surface 211 of the first substrate 210 of the PIC chip 200 may transmit the electrical signal ES to the modulator 224. The modulator 224 may input a signal to light emitted by the laser diode 223 according to the electrical signal ES to convert the electrical signal ES into the optical signal PS.

In FIG. 3, the optical-to-electric conversion unit 220 is illustrated as being buried in a first insulating layer 233. However, the inventive concept is not limited thereto, and the optical-to-electric conversion unit 220 may be covered with an oxide layer distinguished from the first insulating layer 233. That is, the oxide layer may be formed on one side of the first insulating layer 233, and the optical-to-electric conversion unit 220 may be positioned in the oxide layer.

The first wiring structure 230 of the PIC chip 200 may include a plurality of first wiring patterns 231, a plurality of first wiring vias 232 connected to the plurality of first wiring patterns 231, and the first insulating layer 233 on or surrounding the plurality of first wiring patterns 231 and the plurality of first wiring vias 232. In some embodiments, the first wiring structure 230 may have a multilayer wiring structure including the plurality of first wiring patterns 231 and the plurality of first wiring vias 232 at different vertical levels.

In some embodiments, the PIC chip 200 may further include a plurality of lower pads 280 and a lower passivation layer 285 on side surfaces of or surrounding the plurality of lower pads 280. The plurality of lower pads 280 may be on the bottom surface of the PIC chip 200 to be electrically connected to the first through vias 215. The plurality of lower pads 280 of the PIC chip 200 may be electrically connected to the upper pads 170 of the redistribution layer 100 through connection terminals CT2.

In some embodiments, the PIC chip 200 may further include a plurality of upper pads 270 and an upper passivation layer 275 surrounding or on side surfaces of the plurality of upper pads 270. The plurality of upper pads 270 may be on a top surface of the first wiring structure 230 of the PIC chip 200 and may be electrically connected to the plurality of first wiring patterns 231 and/or the plurality of first wiring vias 232.

The buffer chip 300 of the semiconductor package 1000 may include a second substrate 310, a second wiring structure 330, and second through vias 315. The second substrate 310 may include an active surface 311 on which a plurality of individual elements are formed and an inactive surface 312 opposite the active surface 311. The second wiring structure 330 may be formed on the active surface 311 of the second substrate 310. The second through vias 315 may extend from the inactive surface 312 of the second substrate 310 to the active surface 311 thereof. In some embodiments, the second through vias 315 may be electrically connected to the second wiring structure 330 and/or the plurality of individual elements on the active surface 311 of the second substrate 310.

The buffer chip 300 may be on the redistribution layer 100. In some embodiments, the active surface 311 of the buffer chip 300 may face the redistribution layer 100. The buffer chip 300 may be on the redistribution layer 100 so that the active surface 311 of the second substrate 310 faces downward. For example, the buffer chip 300 may be on the redistribution layer 100 in a face-down manner.

The second wiring structure 330 of the buffer chip 300 may include a plurality of second wiring patterns 331, a plurality of second wiring vias 332 connected to the plurality of second wiring patterns 331, and a second insulating layer 333 on or surrounding the plurality of second wiring patterns 331 and the plurality of second wiring vias 332. In some embodiments, the second wiring structure 330 may have a multilayer wiring structure including the plurality of second wiring patterns 331 and the plurality of second wiring vias 332 at different vertical levels.

The buffer chip 300 may include a plurality of upper pads 370 on a top surface thereof and a plurality of lower pads 380 on a bottom surface thereof. The plurality of upper pads 370 and the plurality of lower pads 380 may be surrounded by an upper passivation layer 375 and a lower passivation layer 385, respectively. That is, the upper passivation layer 375 may be on sidewalls of the plurality of upper pads 370, and the lower passivation layer 385 may be on sidewalls of the plurality of lower pads 380.

In some embodiments, the plurality of lower pads 380 may be on the second wiring structure 330 and may be electrically connected to the plurality of second wiring patterns 331 and the plurality of second wiring vias 332. The plurality of lower pads 380 of the buffer chip 300 may be electrically connected to the upper pads 170 of the redistribution layer 100 through connection terminals CT3.

In some embodiments, the plurality of upper pads 380 may be on the inactive surface 312 of the second substrate 310 and may be electrically connected to the second through vias 315. Referring to FIG. 4, some of the plurality of upper pads 380 of the buffer chip 300 may be electrically connected to a plurality of lower pads 480 of the EIC chip 400 through connection terminals CT43, and the others of the plurality of upper pads 380 may be electrically connected to a plurality of lower pads 570 of the plurality of stacked structures 500 through connection terminals CT5.

In some embodiments, an area of the buffer chip 300 may be greater than the sum of areas of the plurality of stacked structures 500. The plurality of stacked structures 500 are on the buffer chip 300, and the buffer chip 300 includes a serial-parallel conversion circuit and may control the plurality of stacked structures 500. Hereinafter, the “area” may mean a horizontal area, that is, an area of a surface parallel to the X-Y plane.

For example, the buffer chip 300 may be referred to as a high-bandwidth memory (HBM) controller die, and each of the plurality of stacked structures 500 may be referred to as a dynamic random access memory (DRAM) stack. The plurality of stacked structures 500 and the buffer chip 300 may be referred to as shared memory modules or compute express link (CXL) memory modules. Because the plurality of stacked structures 500 are all mounted on the buffer chip 300, the semiconductor package 1000 may provide high-capacity memory. Because the buffer chip 300 shares a memory space of the plurality of stacked structures 500, a data processing speed of the semiconductor package 1000 may increase.

In some embodiments, a thickness H_200 of the PIC chip 200 may be substantially equal to a thickness H_300 of the buffer chip 300. For example, a distance from a top surface of the upper passivation layer 275 of the PIC chip 200 to a bottom surface of the lower passivation layer 285 may be substantially equal to a distance from a top surface of the upper passivation layer 375 of the buffer chip 300 to a bottom surface of the lower passivation layer 385.

In some embodiments, a top surface 200_U of the PIC chip 200 may be coplanar with a top surface 300_U of the buffer chip 300. For example, in a process of encapsulating the PIC chip 200 and the buffer chip 300 through a first molding layer ML1, upper portions of the PIC chip 200, the buffer chip 300, and the first molding layer ML1 may be partially ground so that the top surface 200_U of the PIC chip 200, the top surface 300_U of the buffer chip 300, and a top surface ML1_U of the first molding layer ML1 may be coplanar.

In some embodiments, the sum of an area of the PIC chip 200 and the area of the buffer chip 300 may be less than an area of the redistribution layer 100. For example, the redistribution layer 100 may be extended to the outside of the active surfaces of the PIC chip 200 and the buffer chip 300 to extend a region in which the external connection terminals CT1 are positioned. That is, some of the external connection terminals CT1 of the redistribution layer 100 may be on a region of the redistribution layer 100, which does not overlap the PIC chip 200 and the buffer chip 300 in the vertical direction (Z direction). A fan-out wafer level package (FO-WLP) or fan-out panel level package (FO-PLP) (hereinafter, collectively referred to as FO-WLP) structure may be applied to the semiconductor package 1000.

The EIC chip 400 and the plurality of stacked structures 500 will be described in detail with reference to FIG. 4.

The EIC chip 400 of the semiconductor package 1000 may be on the PIC chip 200 and the buffer chip 300. For example, a portion of the EIC chip 400 may overlap the PIC chip 200 in the vertical direction (Z direction), and another portion of the EIC chip 400 may overlap the buffer chip 300 in the vertical direction (Z direction). In some embodiments, a portion of the EIC chip 400 may overlap a physical layer PHY of the buffer chip 300 in the vertical direction (Z direction).

In some embodiments, the EIC chip 400 may overlap the buffer chip 300 and the PIC chip 200. That is, one end portion of the EIC chip 400 may be positioned above the PIC chip 200 in the first horizontal direction (X direction), and the other end portion thereof may be positioned above the buffer chip 300.

In some embodiments, the PIC chip 200 and the buffer chip 300 may be on the redistribution layer 100 to be spaced apart from each other in the horizontal direction. While the EIC chip 400 directly contacts the PIC chip 200 and the buffer chip 300, a portion of the EIC chip 400 may be positioned above a space between the PIC chip 200 and the buffer chip 300.

The EIC chip 400 may include a third substrate 410 and a third wiring structure 430. The third substrate 410 of the EIC chip 400 may include an active surface 411 and an inactive surface 412 opposite the active surface 411. The third wiring structure 430 may be formed on the active surface 411 of the third substrate 410.

In some embodiments, the EIC chip 400 may be on the PIC chip 200 and the buffer chip 300 so that the active surface 411 of the third substrate 410 faces the PIC chip 200. For example, the EIC chip 400 may be on the PIC chip 200 and the buffer chip 300 in a face-down manner.

In some embodiments, the EIC chip 400 may include a plurality of individual elements used by the PIC chip 200 to interface with other individual elements. The plurality of individual elements of the EIC chip 400 may be positioned on the active surface 411 of the third substrate 410. For example, the EIC chip 400 may include complementary metal oxide semiconductor (CMOS) drivers and transimpedance amplifiers to perform functions such as controlling high-frequency signaling of the PIC chip 200.

The EIC chip 400 may electrically connect the PIC chip 200 to the buffer chip 300. Specifically, the EIC chip 400 may input the electrical signal ES converted by the PIC chip 200 to the buffer chip 300 and the electrical signal ES output from the buffer chip 300 to the PIC chip 200.

The third substrate 410 may include a semiconductor material such as Si. Alternatively, the third substrate 410 may include a semiconductor material such as Ge.

The third wiring structure 430 of the EIC chip 400 may include a plurality of third wiring patterns 431, a plurality of third wiring vias 432 connected to the plurality of third wiring patterns 431, and the third insulating layer 433 on or surrounding the plurality of third wiring patterns 431 and the plurality of third wiring vias 432. In some embodiments, the third wiring structure 430 may have a multilayer wiring structure including the plurality of third wiring patterns 431 and the plurality of third wiring vias 432 at different vertical levels.

In some embodiments, the EIC chip 400 may further include the plurality of lower pads 480. The plurality of lower pads 480 may be on a bottom surface of the EIC chip 400 and may be electrically connected to the plurality of third wiring patterns 431 and/or the plurality of third wiring vias 432.

In some embodiments, the plurality of lower pads 480 positioned in a region overlapping the PIC chip 200 in the EIC chip 400 may be electrically connected to the plurality of upper pads 270 of the PIC chip 200 through connection terminals CT42. The plurality of lower pads 480 positioned in a region overlapping the buffer chip 300 in the EIC chip 400 may be electrically connected to the plurality of upper pads 370 of the buffer chip 300 through connection terminals CT43.

The plurality of stacked structures 500 of the semiconductor package 1000 may be on the buffer chip 300. The plurality of stacked structures 500 may be spaced apart from one another in the horizontal direction. Each of the plurality of stacked structures 500 may include a plurality of semiconductor chips 500C.

Each of the plurality of semiconductor chips 500C of the plurality of stacked structures 500 may include a fourth substrate 510 having an active surface 511 including a plurality of individual elements and an inactive surface 512 opposite the active surface 511, and a fourth wiring structure 530 formed on the active surface 511 of the fourth substrate 510.

In some embodiments, semiconductor chips excluding the semiconductor chip positioned at the top of the plurality of semiconductor chips 500C of each of the plurality of stacked structures 500 may further include a plurality of fourth through electrodes 515 connected to the fourth wiring structure 530 and passing through the fourth substrate 510. Among the plurality of semiconductor chips 500C, the uppermost semiconductor chip farthest from the buffer chip 300 may not include the plurality of fourth through electrodes 515. However, the inventive concept is not limited thereto, and the uppermost semiconductor chip may include the plurality of fourth through electrodes 515.

In some embodiments, a thickness of each of the plurality of semiconductor chips 500C, that is, a length of each of the plurality of semiconductor chips 500C in the vertical direction (Z direction), may be about 20 μm to about 80 μm. Thicknesses of the plurality of semiconductor chips 500C may have substantially the same value.

In some embodiments, each of the plurality of stacked structures 500 may further include a dummy chip (not shown). The dummy chip may be positioned at the top of each of the plurality of stacked structures 500. That is, the dummy chip may be stacked on the uppermost semiconductor chip. The dummy chip may include, for example, a semiconductor material such as Si. In some embodiments, the dummy chip may include only a semiconductor material. For example, the dummy chip may be a portion of a bare wafer.

In the semiconductor package 1000, the plurality of semiconductor chips 500C may be sequentially stacked on the buffer chip 300 in the vertical direction (Z direction) while the active surface 511 faces downward, that is, the buffer chip 300.

In some embodiments, the plurality of semiconductor chips 500C may include memory chips. The memory chip may include a volatile memory semiconductor device such as DRAM or static random access memory (SRAM), or a non-volatile memory semiconductor device such as phase-change random access memory (PRAM), magnetoresistive random access memory (MRAM), ferroelectric random access memory (FeRAM), or resistive random access memory (RRAM).

Each of the plurality of stacked structures 500 may further include bonding layers BL. The bonding layers BL are positioned among the plurality of semiconductor chips 500C, and may electrically and physically connect the plurality of semiconductor chips 500C to one another. Each of the bonding layers BL may include a plurality of bonding pads BL1 and a bonding insulating layer BL2.

Specifically, the fourth wiring structure 530 of the semiconductor chip 500C excluding the lowermost semiconductor chip closest to the buffer chip 300 among the plurality of semiconductor chips 500C may be electrically connected to the plurality of fourth through electrodes 515 of another semiconductor chip 500C positioned below through the plurality of bonding pads BL1. The bonding insulating layers BL2 may be positioned between the plurality of semiconductor chips 500C to surround or be on side surfaces of the plurality of bonding pads BL1.

Each of the plurality of bonding pads BL1 may be formed by forming conductive material layers on facing surfaces of two adjacent chips among the plurality of semiconductor chips 500C, by expanding the conductive material layers facing each other by heat to contact each other, and by performing diffusion bonding on the conductive material layers so that the conductive material layers form one body through diffusion of metal atoms in each of the conductive material layers.

The bonding insulating layer BL2 may be formed in a process of forming insulating material layers on facing surfaces of two adjacent chips among the plurality of semiconductor chips 500C and then, forming the plurality of bonding pads BL1. In the above process, the insulating material layers facing each other expand by heat to contact each other, and the bonding insulating layer BL2 may be formed through diffusion bonding in which atoms in each insulating material layer diffuse at a contact surface.

In some embodiments, a thickness H_400 of the EIC chip 400 may be substantially equal to a thickness H_500 of each of the plurality of stacked structures 500. For example, a distance from a top surface of the third substrate 410 of the EIC chip 400 to a bottom surface of the third wiring structure 430 may be substantially equal to a distance from a top surface of the uppermost semiconductor chip of the plurality of stacked structures 500 to a bottom surface of the lowermost semiconductor chip thereof.

In some embodiments, a top surface 400_U of the EIC chip 400 may be coplanar with a top surface 500_U of each of the plurality of stacked structures 500. For example, in a process of encapsulating the EIC chip 400 and the plurality of stacked structures 500 through a second molding layer ML2, upper portions of the EIC chip 400, the plurality of stacked structures 500, and the second molding layer ML2 may be partially ground so that the top surface 400_U of the EIC chip 400, the top surface 500_U of each of the plurality of stacked structures 500, and a top surface ML2_U of the second molding layer ML2 may be coplanar.

Referring back to FIGS. 1 and 2, the molding layer ML of the semiconductor package 1000 may be on or cover the top surface of the redistribution layer 100 and may surround or be on side surfaces of the PIC chip 200, the buffer chip 300, the EIC chip 400, and the plurality of stacked structures 500. In some embodiments, side surfaces of the molding layer ML may be coplanar with side surfaces of the redistribution layer 100. In some embodiments, the molding layer ML may include an epoxy mold compound (EMC).

The molding layer ML may include a through hole ML_H extending inward from a top surface thereof. The through hole ML_H may be positioned on the PIC chip 200. The optical fiber 600 may be positioned in the through hole ML_H. For example, the through hole ML_H is positioned above the optical-to-electric conversion unit 220 of the PIC chip 200 so that the optical signal PS may be input from the optical fiber 600 positioned in the through hole ML_H to the optical-to-electric conversion unit 220 or may be output from the optical-to-electric conversion unit 220 to the optical fiber 600.

In some embodiments, the molding layer ML may include a plurality of through holes ML_H, and the optical fiber 600 may be positioned in each of the plurality of through holes ML_H. Some of the plurality of optical fibers may transmit the optical signal PS to the PIC chip 200, and others may receive the optical signal PS from the PIC chip 200. In FIG. 2, the optical fiber 600 extends straight in the vertical direction (Z direction). However, the shape of the optical fiber 600 is not limited thereto.

In some embodiments, the molding layer ML may include the first molding layer ML1 and the second molding layer ML2. The first molding layer ML1 may cover or be on at least a portion of the top surface of the redistribution layer 100 and may surround or be on side surfaces of the PIC chip 200 and the buffer chip 300. The second molding layer ML2 may cover or be on at least a portion of the top surface of the first molding layer ML1 and may surround or be on side surfaces of the EIC chip 400 and the plurality of stacked structures 500.

In some embodiments, because the first molding layer ML1 and the second molding layer ML2 may be formed of different materials, the molding layer ML may have an interface between the first molding layer ML1 and the second molding layer ML2. However, in some embodiments, although the first molding layer ML1 and the second molding layer ML2 may be formed of the same material, because a curing point of the first molding layer ML1 is different from a curing point of the second molding layer ML2, the molding layer ML may have an interface between the first molding layer ML1 and the second molding layer ML2.

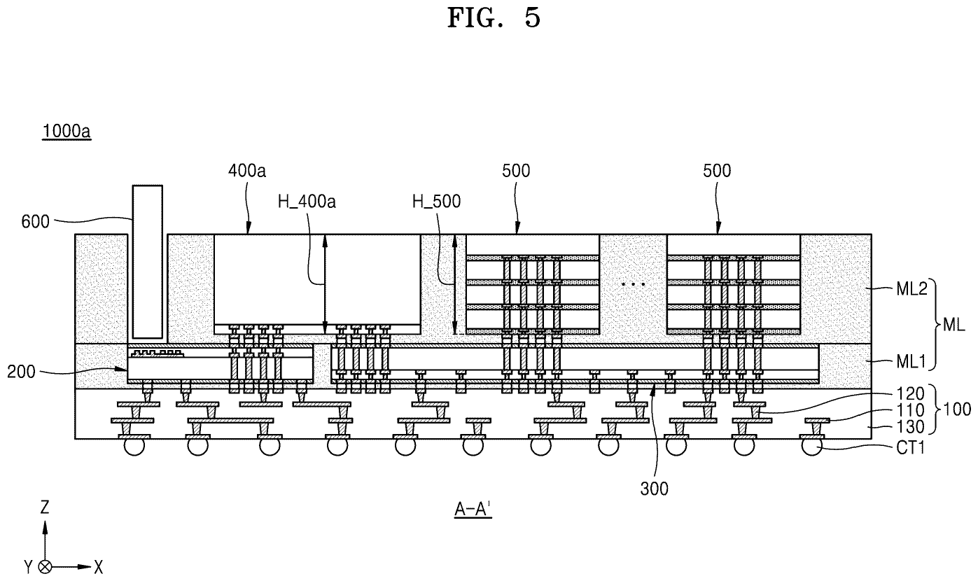

FIGS. 5 to 8 are cross-sectional views schematically illustrating semiconductor packages 1000a, 1000b, and 1000c according to embodiments, taken along the line A-A′ of FIG. 1.

Most of components of the semiconductor packages 1000a, 1000b, and 1000c described below and materials of the components are substantially the same as or similar to those described above with reference to FIG. 2. Therefore, for convenience, differences between the semiconductor packages 1000a, 1000b, and 1000c of FIGS. 5 to 8 and the semiconductor package 1000 of FIG. 2 described above will be mainly described.

Referring to FIG. 5, an EIC chip 400a of the semiconductor package 1000a may be positioned on a PIC chip 200 and a buffer chip 300. A portion of the EIC chip 400a may overlap the PIC chip 200 in the vertical direction (Z direction), and the other portion of the EIC chip 400a may overlap the buffer chip 300 in the vertical direction (Z direction). For example, one end portion of the EIC chip 400a may be positioned above the PIC chip 200, and the opposite end portion of the EIC chip 400a may be positioned above the buffer chip 300.

A thickness H_400a of the EIC chip 400a may be different from a thickness H_500 of each of a plurality of stacked structures 500. For example, the thickness H_400a of the EIC chip 400a may be less than the thickness H_500 of each of the plurality of stacked structures 500.

The EIC chip 400a may be surrounded by a molding layer ML. That is, the molding layer ML may be on side surfaces of the EIC chip 400a. In detail, the EIC chip 400a may be surrounded by a second molding layer ML2. That is, the second molding layer ML2 may be on side surfaces of the EIC chip 400a.

A bottom surface of each of the plurality of stacked structures 500 and a bottom surface of the EIC chip 400a are attached to a top surface of the buffer chip 300 through connection terminals so that a vertical level of the bottom surface of each of the plurality of stacked structures 500 may be substantially the same as a vertical level of the bottom surface of the EIC chip 400a. In contrast, the top surface of each of the plurality of stacked structures 500 is coplanar with a top surface of the second molding layer ML2, and a top surface of the EIC chip 400a may be positioned in the second molding layer ML2. That is, the EIC chip 400a may be buried in the second molding layer ML2. In other words, the EIC chip 400a may not be exposed.

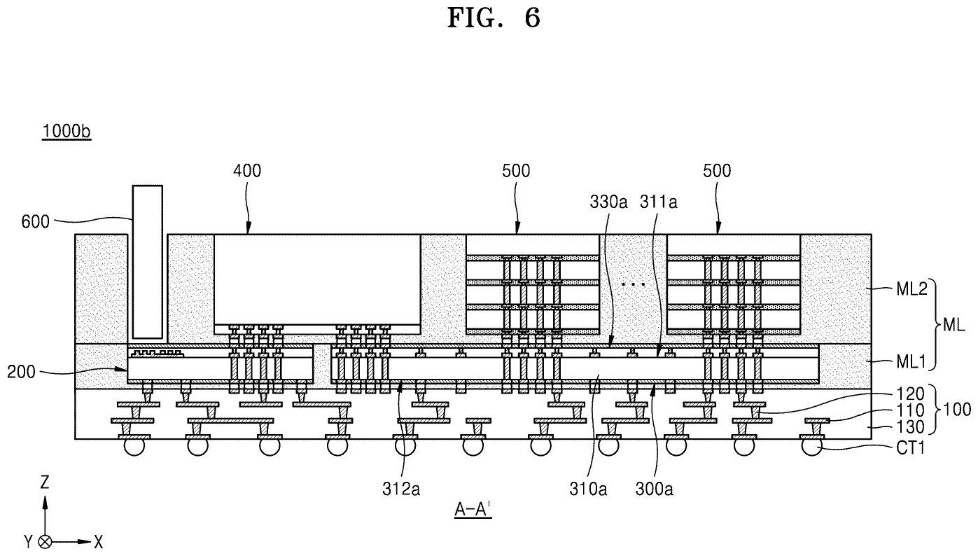

Referring to FIG. 6, a buffer chip 300a of the semiconductor package 1000b may be on a redistribution layer 100. The buffer chip 300a may include a second substrate 310a including an active surface 311a, on which a plurality of individual elements are formed, and an inactive surface 312a opposite the active surface 311a, a second wiring structure 330a, and the second through vias 315 (refer to FIG. 3).

The buffer chip 300a may be on the redistribution layer 100 so that the active surface 311a of the second substrate 310a faces upward. For example, the buffer chip 300a may be on the redistribution layer 100 so that the inactive surface 312a of the second substrate 310a faces the redistribution layer 100.

The second wiring structure 330a may be formed on the active surface 311a of the second substrate 310a. That is, the second wiring structure 330a may be spaced apart from the redistribution layer 100 in the vertical direction (Z direction) with the second substrate 310a therebetween. Accordingly, upper pads of the buffer chip 300a may be electrically connected to the second wiring structure 330a, and lower pads of the buffer chip 300a may be electrically connected to the second through vias.

A signal distance between the active surface 311a of the second substrate 310a of the buffer chip 300a and an EIC chip 400 may be reduced so that signal accuracy of the semiconductor package 1000a may be improved.

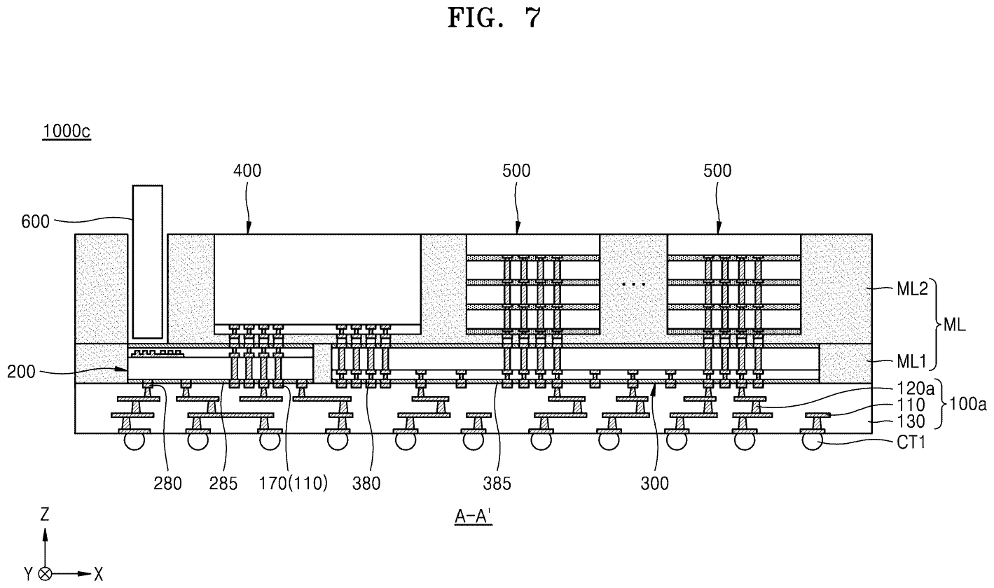

Referring to FIG. 7, a redistribution layer 100a may include wiring lines 110, vertical vias 120a vertically connecting the wiring lines 110, and an insulating layer 130 surrounding or on the wiring lines 110 and the vertical vias 120a.

In some embodiments, structurally, each of the vertical vias 120a in the redistribution layer 100a may have a width in the first horizontal direction (X direction) and/or a width in the second horizontal direction (Y direction) gradually decreasing toward a bottom surface of a PIC chip 200. That is, a horizontal area of each of the vertical vias 120a of the redistribution layer 100a may increase toward a top surface thereof. For example, the semiconductor package 1000c may be manufactured in a chip-first method.

After a first molding layer ML1, the PIC chip 200, and a buffer chip 300 are formed, the redistribution layer 100a may be formed. A bottom surface of the first molding layer ML1, a bottom surface of the PIC chip 200, and a bottom surface of the buffer chip 300 may be coplanar.

Lower pads 280 and a lower passivation layer 285 of the PIC chip 200 may directly contact a top surface of the redistribution layer 100a. For example, the lower pads 280 of the PIC chip 200 may directly contact upper pads 170 of the redistribution layer 100a corresponding thereto. Lower pads 380 and a lower passivation layer 385 of the buffer chip 300 may directly contact the top surface of the redistribution layer 100a. For example, the lower pads 380 of the buffer chip 300 may directly contact the upper pads 170 of the redistribution layer 100a corresponding thereto.

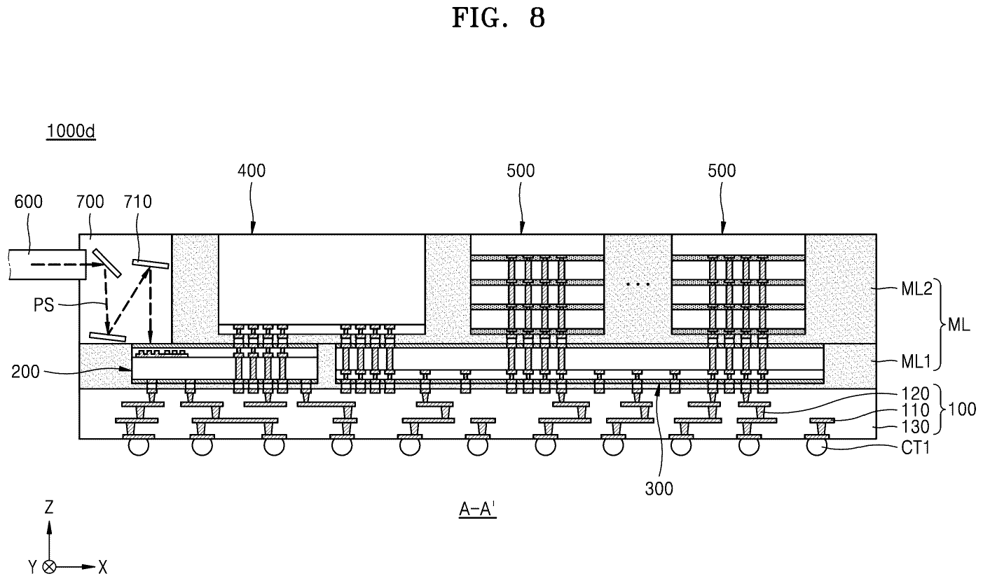

Referring to FIG. 8, the semiconductor package 1000d may further include a reflector 700. An optical fiber 600 may be inserted into the reflector 700 so that an optical signal PS emitted by the optical fiber 600 may flow into the reflector 700.

In some embodiments, the reflector 700 may include a body formed of a transparent material transmitting light and a plurality of mirrors 710 in the body configured to reflect the light. For example, the body may include at least one of glass and quartz.

The plurality of mirrors 710 may be under incidence/reflection conditions so that the optical signal PS emitted from the optical fiber 600 flows into the PIC chip 200. In some embodiments, the optical signal PS reflected by the plurality of mirrors 710 may flow into the optical-to-electric conversion unit 220 (refer to FIG. 3) of the PIC chip 200. In FIG. 8, the reflector 700 is illustrated as a single layer. However, the reflector 700 may have a multilayer structure, and the plurality of mirrors 710 may be positioned among layers.

A portion of the reflector 700 may overlap the PIC chip 200 in the vertical direction (Z direction). The reflector 700 may improve accuracy with which the optical signal PS emitted from the optical fiber 600 flows into the grating coupler 221 of the PIC chip 200.

In FIG. 8, the optical fiber 600 is illustrated as being inserted into one sidewall of the reflector 700. However, an insertion direction and a position of the optical fiber 600 are not limited thereto. In addition, it is illustrated in FIG. 8 that one side of the reflector 700 contacts the second molding layer ML2, and the other side thereof is exposed or free from the molding layer ML2. However, the inventive concept is not limited thereto, and all sides of the reflector 700 may contact the second molding layer ML2.

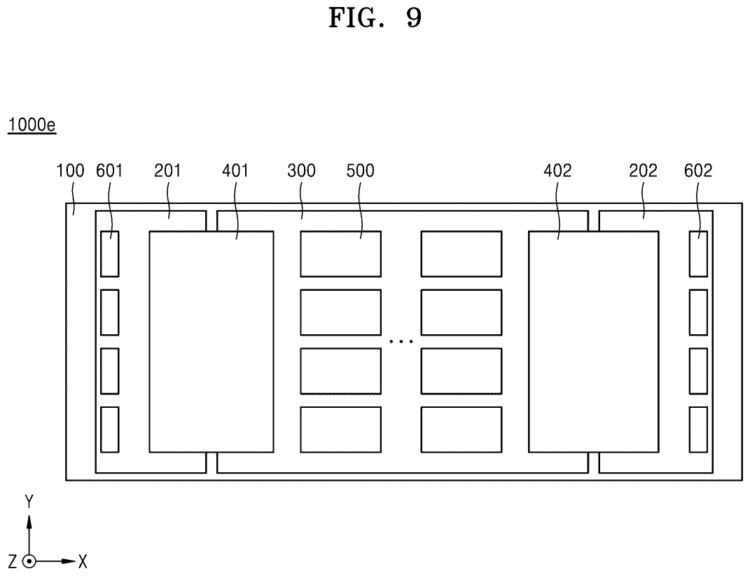

FIGS. 9 to 11 are plan views schematically illustrating semiconductor packages 1000e, 1000f, and 1000g according to embodiments.

Most of components of the semiconductor packages 1000e, 1000f, and 1000g described below and materials of the components are substantially the same as or similar to those described above with reference to FIG. 1. Therefore, for convenience, differences between the semiconductor packages 1000e, 1000f, and 1000g of FIGS. 9 to 11 and the semiconductor package 1000 of FIG. 1 described above will be mainly described.

Referring to FIG. 9, the semiconductor package 1000e may include a first PIC chip 201, a first EIC chip 401, a first optical fiber 601, a second PIC chip 202, a second EIC chip 402, and a second optical fiber 602.

The first PIC chip 201 and the second PIC chip 202 may be on a redistribution layer 100. The first PIC chip 201 and the second PIC chip 202 may be substantially the same as the PIC chip 200 (refer to FIG. 2) described above.

The first PIC chip 201 and the second PIC chip 202 may be spaced apart from each other in the horizontal direction with a buffer chip 300 therebetween. That is, the first PIC chip 201 and the second PIC chip 202 may be positioned on both sides of the buffer chip 300.

The first EIC chip 401 and the second EIC chip 402 may be spaced apart from each other in the horizontal direction with a plurality of stacked structures 500 therebetween. The first EIC chip 401 and the second EIC chip 402 may be substantially the same as the EIC chip 400 (refer to FIG. 2) described above.

The first EIC chip 401 may be positioned on the first PIC chip 201 and the buffer chip 300. For example, a portion of the first EIC chip 401 may overlap the first PIC chip 201 in the vertical direction, and another portion of the first EIC chip 401 may overlap the buffer chip 300 in the vertical direction. For example, a portion of the first EIC chip 401 may be positioned above a space between the first PIC chip 201 and the buffer chip 300.

The second EIC chip 402 may be positioned on the second PIC chip 202 and the buffer chip 300. A portion of the second EIC chip 402 may overlap the second PIC chip 202 in the vertical direction, and another portion of the second EIC chip 402 may overlap the buffer chip 300 in the vertical direction. For example, a portion of the second EIC chip 402 may be positioned above a space in which the second PIC chip 202 is spaced apart from the buffer chip 300.

The first optical fiber 601 may be positioned above the first PIC chip 201, and the second optical fiber 602 may be positioned above the second PIC chip 202. The first optical fiber 601 may input/output an optical signal to/from the first PIC chip 201, and the second optical fiber 602 may input/output an optical signal to/from the second PIC chip 202.

In some embodiments, the first PIC chip 201 may convert an optical signal into an electronic signal, and the second PIC chip 202 may convert an electronic signal into an optical signal. Accordingly, the first optical fiber 601 may input an optical signal, and the second optical fiber 602 may output an optical signal.

It is illustrated in FIG. 9 that two PIC chips are mounted on the redistribution layer 100. However, the number of PIC chips is not limited thereto.

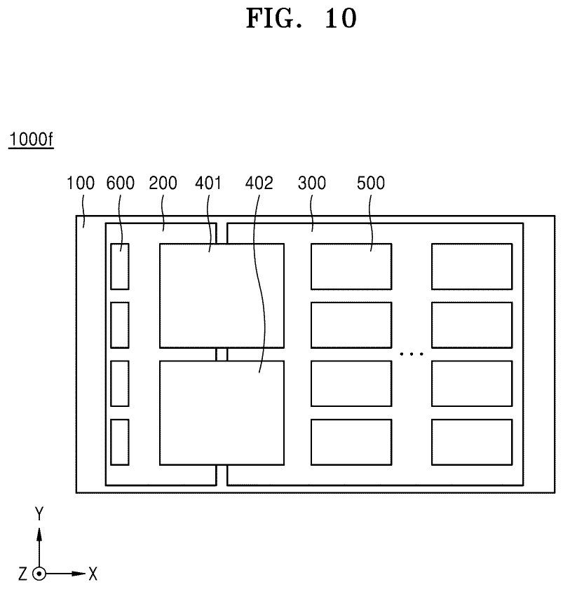

Referring to FIG. 10, the semiconductor package 1000f may include a first EIC chip 401 and a second EIC chip 402. The first EIC chip 401 and the second EIC chip 402 may be substantially the same as the EIC chip 400 (refer to FIG. 2) described above.

The first EIC chip 401 and the second EIC chip 402 may be positioned above a PIC chip 200 and a buffer chip 300. That is, a plurality of EIC chips may be mounted on one PIC chip 200.

In some embodiments, when the PIC chip 200 is spaced apart from the buffer chip 300 in the first horizontal direction (X direction), the first EIC chip 401 may be spaced apart from the second EIC chip 402 in the second horizontal direction (Y direction).

In some embodiments, the first EIC chip 401 and the second EIC chip 402 may separately operate. Accordingly, the amount of heat generated by each of the first EIC chip 401 and the second EIC chip 402 may be relatively reduced. Accordingly, the thermal management efficiency of the semiconductor package 1000f may be improved.

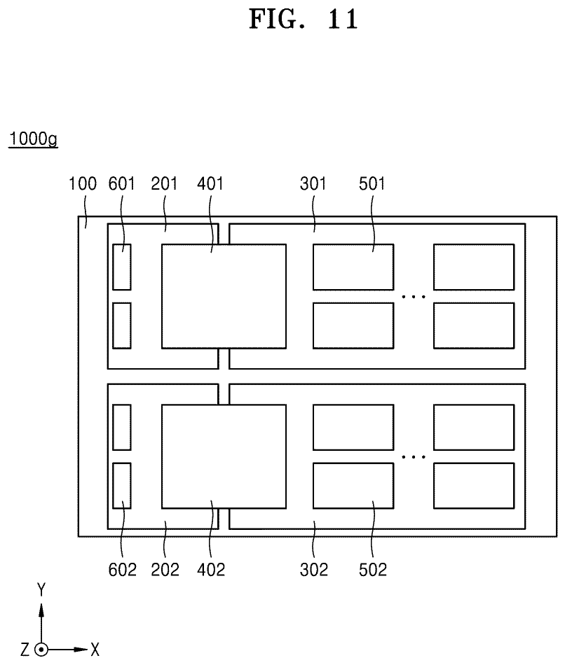

Referring to FIG. 11 together with FIG. 2, the semiconductor package 1000g may include a redistribution layer 100, first and second PIC chips 201 and 202, first and second buffer chips 301 and 302, first and second EIC chips 401 and 402, a plurality of first and second stacked structures 501 and 502, and first and second optical fibers 601 and 602.

The first PIC chip 201, the first buffer chip 301, the first EIC chip 401, the plurality of first stacked structures 501, and the first optical fiber 601 may have substantially the same structures and materials as those of the PIC chip 200, the buffer chip 300, the EIC chip 400, the plurality of stacked structures 500, and the optical fiber 600 described above.

The second PIC chip 202, the second buffer chip 302, the second EIC chip 402, the plurality of second stacked structures 502, and the second optical fiber 602 may have substantially the same structures and materials as those of the PIC chip 200, the buffer chip 300, the EIC chip 400, the plurality of stacked structures 500, and the optical fiber 600 described above.

The first PIC chip 201, the first buffer chip 301, the first EIC chip 401, and the plurality of first stacked structures 501 may be referred to as a first module and the second PIC chip 202, the second buffer chip 302, the second EIC chip 402, and the plurality of second stacked structures 502 may be referred to as a second module.

The first module and the second module may be mounted on the redistribution layer 100 to be spaced apart from each other in the horizontal direction. That is, a plurality of modules may be mounted on one redistribution layer 100. It is illustrated in FIG. 11 that the number of modules on the redistribution layer 100 is two. However, the number of modules is not limited thereto.

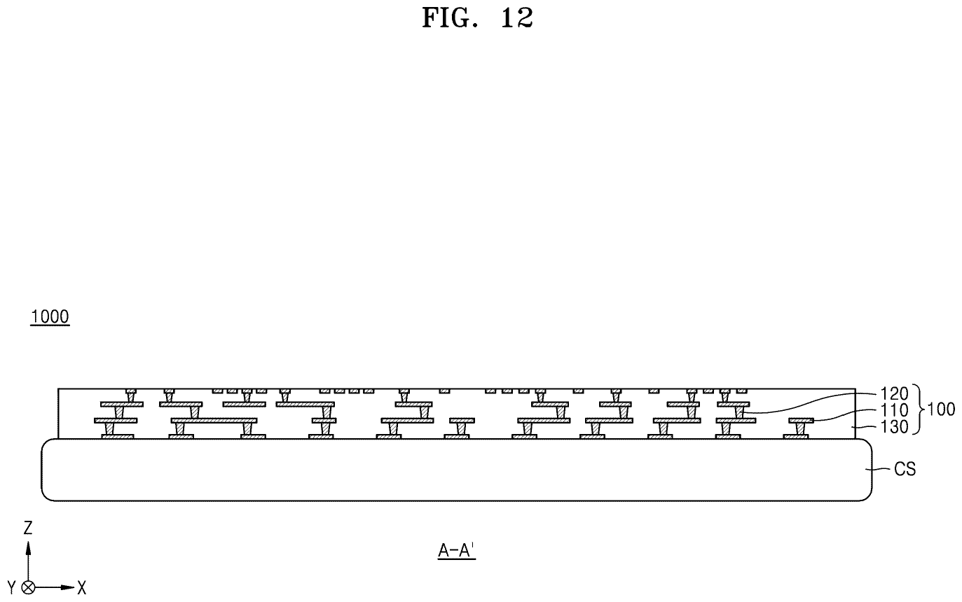

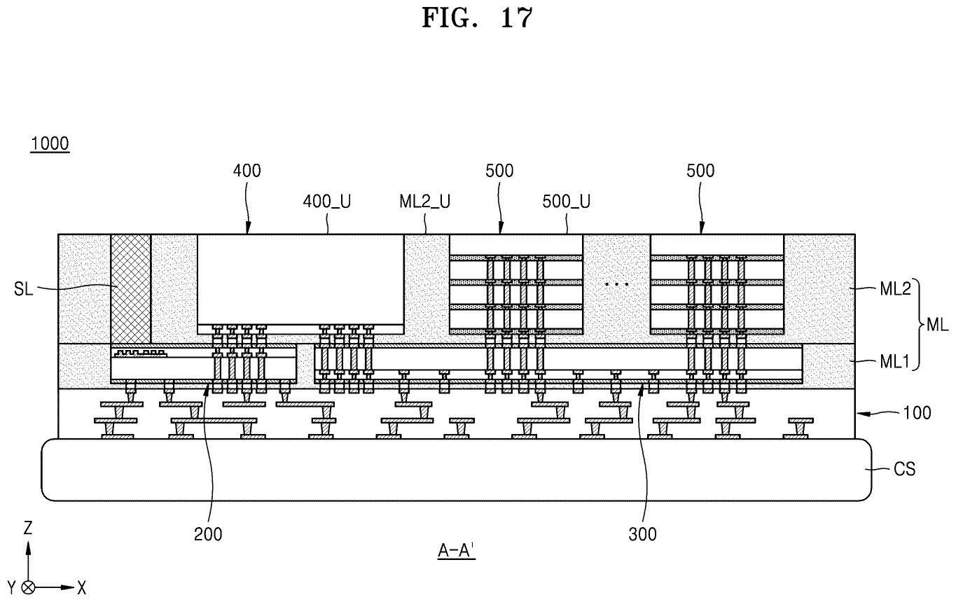

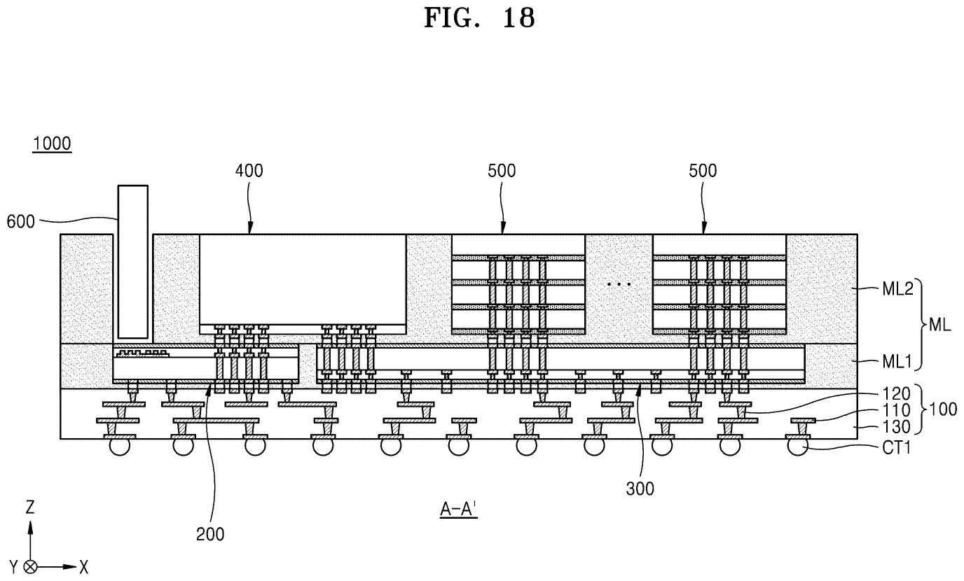

FIGS. 12 to 18 are views illustrating a method of manufacturing a semiconductor package according to some embodiments.

Referring to FIG. 12, the redistribution layer 100 may be formed on a carrier substrate CS.

The carrier substrate CS may include, for example, glass, Si, or aluminum oxide. The redistribution layer 100 may be formed on the carrier substrate CS by recess and plating processes. The redistribution layer 100 may include the wiring lines 110, the vertical vias 120, and the insulating layer 130. For example, after forming the insulating layer 130, a process of forming the vertical vias 120 and/or the wiring lines 110 by the recess process may be repeated to form the redistribution layer 100 with a multilayer structure.

In some embodiments, structurally, each of the vertical vias 120 in the redistribution layer 100 may have a width in the first horizontal direction (X direction) and/or a width in the second horizontal direction (Y direction) gradually increasing away from the carrier substrate CS.

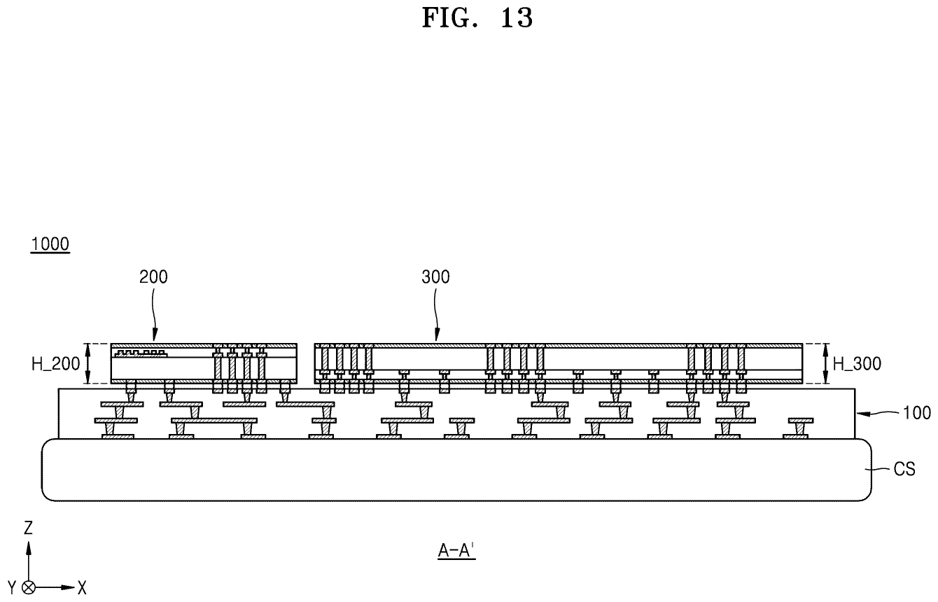

Referring to FIG. 13, the PIC chip 200 and the buffer chip 300 may be mounted on the redistribution layer 100.

The PIC chip 200 may be spaced apart from the buffer chip 300 in the horizontal direction. The area of the redistribution layer 100 may be greater than the sum of the area of the PIC chip 200 and the area of the buffer chip 300.

In some embodiments, the PIC chip 200 may be mounted on the redistribution layer 100 so that the active surface of the PIC chip 200 faces upward, and the buffer chip 300 may be mounted on the redistribution layer 100 so that the active surface of the buffer chip 300 faces downward.

In some embodiments, the thickness H_200 of the PIC chip 200 may be equal to the thickness H_300 of the buffer chip 300. However, the inventive concept is not limited thereto, and the thickness H_200 of the PIC chip 200 may be different from the thickness H_300 of the buffer chip 300.

After attaching connection terminals to lower pads of each of the PIC chip 200 and the buffer chip 300, and positioning the connection terminals to contact corresponding upper pads of the redistribution layer 100, a reflow process may be performed.

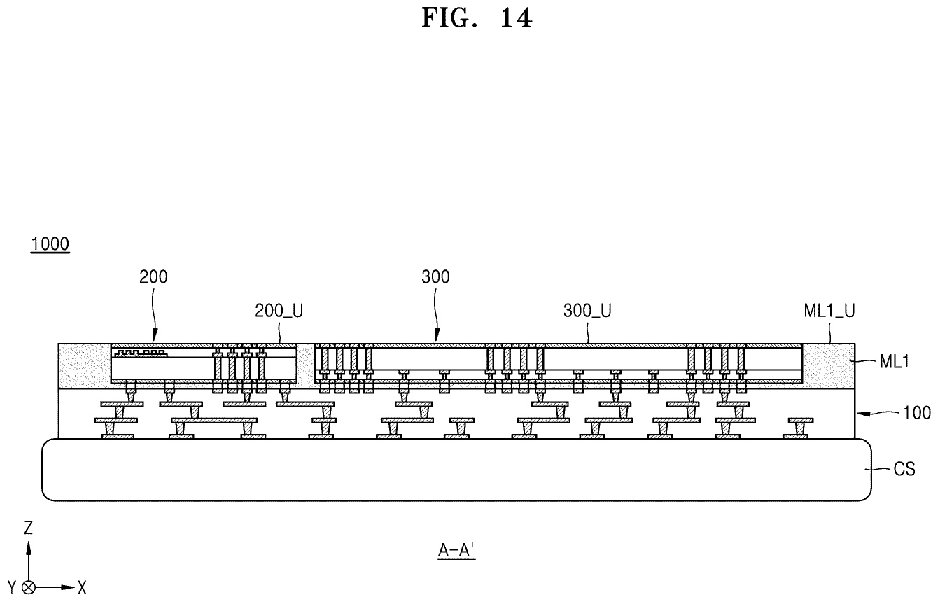

Referring to FIG. 14, encapsulation of the PIC chip 200 and the buffer chip 300 may be performed.

The first molding layer ML1 on or covering the redistribution layer 100 and surrounding or on side surfaces of the PIC chip 200 and the buffer chip 300 may be formed. For example, after the first molding layer ML1 is formed on the PIC chip 200 and the buffer chip 300, the upper portion of the first molding layer ML1 may be removed by a polishing process so that the top surface 200_U of the PIC chip 200 and the top surface 300_U of the buffer chip 300 are exposed or free from the first molding layer ML1.

After the polishing process is performed, the top surface of the first molding layer ML1, the top surface 200_U of the PIC chip 200, and the top surface 300_U of the buffer chip 300 may be coplanar. For example, although the thicknesses H_200 of the PIC chip 200 is different from the thickness H_300 of the buffer chip 300, the thicknesses H_200 of the PIC chip 200 may become substantially equal to the thickness H_300 of the buffer chip 300 as the polishing process is performed.

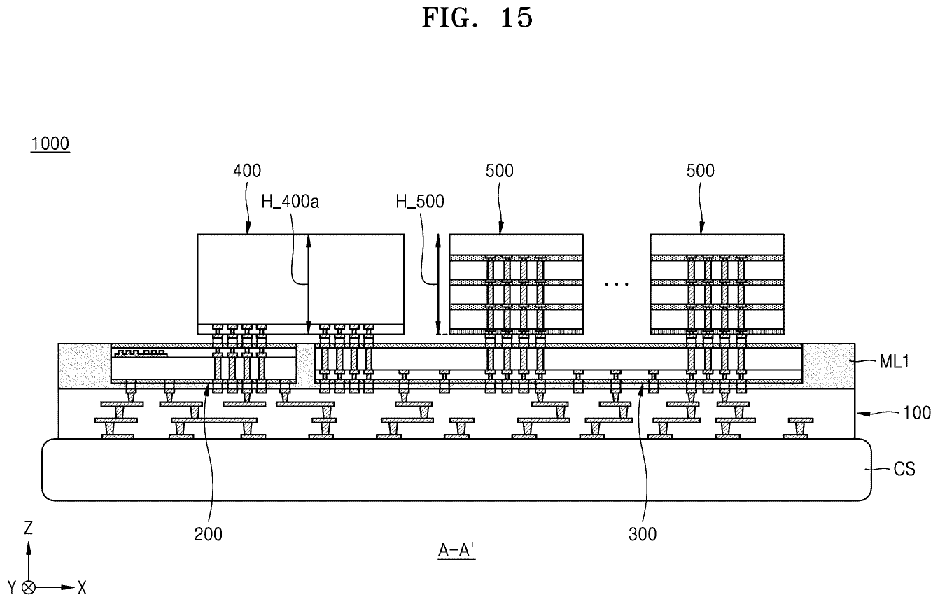

Referring to FIG. 15, the EIC chip 400 and the plurality of stacked structures 500 may be mounted on the result of FIG. 14.

The EIC chip 400 may be mounted on the PIC chip 200 and the buffer chip 300. For example, the EIC chip 400 may be mounted on the PIC chip 200 and the buffer chip 300 so that the active surface of the EIC chip 400 faces the PIC chip 200.

In some embodiments, a portion of the EIC chip 400 may overlap the PIC chip 200, and the other portion of the EIC chip 400 may overlap the buffer chip 300. The EIC chip 400 may be configured to control an electrical signal between the PIC chip 200 and the buffer chip 300.

The plurality of stacked structures 500 may be mounted on the buffer chip 300 to be spaced apart from one another in the horizontal direction. For example, each of the plurality of stacked structures 500 may have a shape in which a plurality of memory chips are stacked. In some embodiments, each of the plurality of stacked structures 500 may have a shape in which four DRAMs are stacked by direct bonding.

In some embodiments, the thickness H_500 of each of the plurality of stacked structures 500 may be substantially equal to the thickness H_400 of the EIC chip 400. However, the inventive concept is not limited thereto, and the thickness H_500 of each of the plurality of stacked structures 500 may be different from the thickness H_400 of the EIC chip 400.

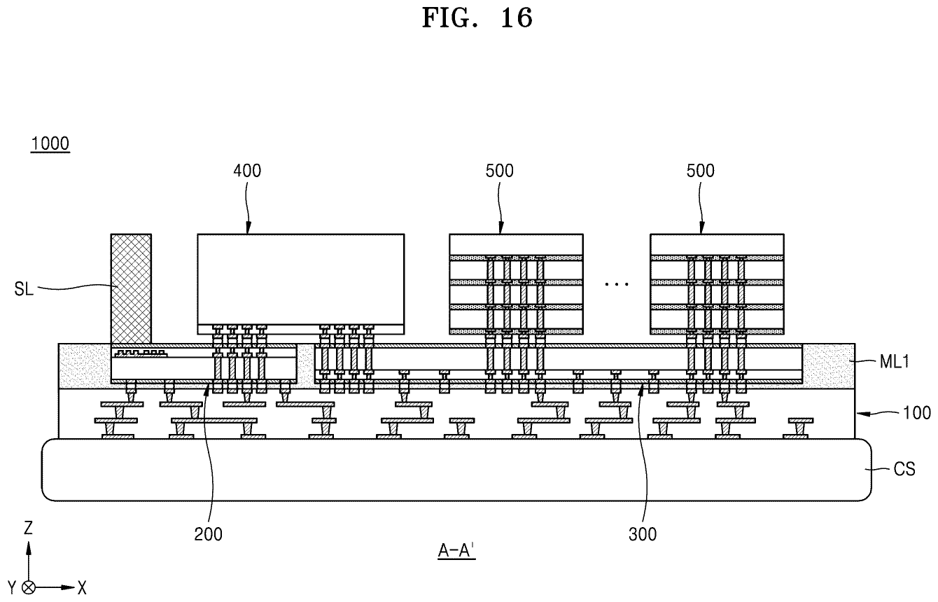

Referring to FIGS. 16 to 18, encapsulation of the EIC chip 400 and the plurality of stacked structures 500 may be performed.

By a photolithography process and an etching process, a sacrificial layer SL may be formed on the PIC chip 200. The second molding layer ML2 may be on or cover the first molding layer ML1 and surround or be on side surfaces of the sacrificial layer SL, the EIC chip 400, and the plurality of stacked structures 500.

Next, the upper portion of the second molding layer ML2 may be removed by the polishing process so that the top surface 500_U of each of the plurality of stacked structures 500 is exposed or free from the second molding layer ML2. In some embodiments, after the polishing process is performed, the top surface ML2_U of the second molding layer ML2, the top surface 400_U of the EIC chip 400, and the top surface 500_U of each of the plurality of stacked structures 500 may be coplanar. For example, when the thickness H_400 of the EIC chip 400 is equal to or greater than the thickness H_500 of each of the plurality of stacked structures 500, the thickness H_400 of the EIC chip 400 may be substantially equal to the thickness H_500 of each of the plurality of stacked structures 500 as the polishing process is performed.

In some embodiments, when the thickness H_400 of the EIC chip 400 is less than the thickness H_500 of each of the plurality of stacked structures 500, the EIC chip 400 may be buried in the second molding layer ML2 although the polishing process is performed.

In some embodiments, the curing point of the first molding layer ML1 may be different from the curing point of the second molding layer ML2. Accordingly, although the first molding layer ML1 and the second molding layer ML2 are formed of the same material, the molding layer ML may have an interface between the first molding layer ML1 and the second molding layer ML2.

Next, after the through hole ML_H is formed by removing the sacrificial layer SL, the optical fiber 600 may be inserted into the through hole ML_H. Accordingly, the optical fiber 600 may be positioned on the PIC chip 200. The carrier substrate CS may be removed, and the external connection terminals CT1 may be attached to the bottom surface of the redistribution layer 100.

While the inventive concept has been particularly shown and described with reference to embodiments thereof, it will be understood that various changes in form and details may be made therein without departing from the spirit and scope of the following claims.

What is claimed is:

1. A semiconductor package comprising:
a redistribution layer;
a photonic integrated circuit (PIC) chip on the redistribution layer;
a buffer chip on the redistribution layer;
an electronic integrated circuit (EIC) chip on the PIC chip and the buffer chip; and
a plurality of stacked structures on the buffer chip, each of the plurality of stacked structures including a plurality of stacked semiconductor chips, wherein the plurality of stacked structures are spaced apart from one another in a horizontal direction, and
wherein a portion of the EIC chip overlaps the PIC chip in a vertical direction, and another portion of the EIC chip overlaps the buffer chip in a vertical direction.

2. The semiconductor package of claim 1, wherein the PIC chip is spaced apart from the buffer chip in a horizontal direction, and
wherein at least a portion of the EIC chip is positioned above a space between the PIC chip and the buffer chip.

3. The semiconductor package of claim 1, wherein a thickness of the PIC chip is equal to a thickness of the buffer chip.

4. The semiconductor package of claim 1, wherein the PIC chip comprises an active surface, an inactive surface opposite the active surface, and through vias, and
wherein the inactive surface of the PIC chip faces the redistribution layer.

5. The semiconductor package of claim 4, wherein the buffer chip comprises an active surface, an inactive surface opposite the active surface, and through vias, and
wherein the active surface of the buffer chip faces the redistribution layer.

6. The semiconductor package of claim 1, wherein a sum of an area of the PIC chip and an area of the buffer chip is less than an area of the redistribution layer.

7. The semiconductor package of claim 1, wherein a thickness of each of the plurality of stacked structures is equal to a thickness of the EIC chip.

8. The semiconductor package of claim 1, wherein the EIC chip comprises an active surface and an inactive surface opposite the active surface, and
wherein the active surface of the EIC chip faces the PIC chip.

9. The semiconductor package of claim 1, wherein the plurality of semiconductor chips of each of the plurality of stacked structures comprise memory chips.

10. The semiconductor package of claim 1, further comprising a plurality of optical fibers configured to input/output optical signals to/from the PIC chip, wherein the plurality of optical fibers are positioned on the PIC chip.

11. A semiconductor package comprising:
a redistribution layer;
a photonic integrated circuit (PIC) chip on the redistribution layer and configured to convert an optical signal into an electrical signal;
a buffer chip on the redistribution layer and spaced apart from the PIC chip in a horizontal direction;
an electronic integrated circuit (EIC) chip above the PIC chip and the buffer chip, and having one end portion positioned above the PIC chip and the other end portion positioned above the buffer chip in a first horizontal direction;
a plurality of stacked structures on the buffer chip, each of the plurality of stacked structures including a plurality of stacked semiconductor chips; and
a molding layer on a top surface of the redistribution layer and side surfaces of the PIC chip, the buffer chip, the EIC chip, and the plurality of stacked structures, wherein a plurality of stacked structures are spaced apart from one another in a horizontal direction.

12. The semiconductor package of claim 11, wherein the molding layer comprises a first molding layer and a second molding layer, wherein the first molding layer is on side surfaces of the PIC chip and the buffer chip, wherein the second molding layer is on sides surfaces of the EIC chip and the plurality of stacked structures, and
wherein an interface is provided between the first molding layer and the second molding layer.

13. The semiconductor package of claim 12, wherein a top surface of the first molding layer, a top surface of the PIC chip, and a top surface of the buffer chip are coplanar.

14. The semiconductor package of claim 12, wherein a top surface of the second molding layer, a top surface of the EIC chip, and a top surface of each of the plurality of stacked structures are coplanar.

15. The semiconductor package of claim 11, further comprising an optical fiber configured to input/output an optical signal to/from the PIC chip, wherein the molding layer comprises a through hole positioned on the PIC chip, and
wherein the optical fiber is positioned in the through hole.

16. The semiconductor package of claim 11, wherein side surfaces of the molding layer are coplanar with side surfaces of the redistribution layer.

17. A semiconductor package comprising:
a redistribution layer;
a photonic integrated circuit (PIC) chip on the redistribution layer and including an optical-to-electric conversion unit;
a buffer chip on the redistribution layer and spaced apart from the PIC chip in a horizontal direction;
an electronic integrated circuit (EIC) chip on the PIC chip and the buffer chip and positioned to overlap the PIC chip and the buffer chip;
a plurality of stacked structures on the buffer chip, each of the plurality of stacked structures including a plurality of stacked semiconductor chips, and being spaced apart from one another in a horizontal direction;
an optical fiber positioned above the optical-to-electric conversion unit of the PIC chip; and
a molding layer on at least a portion of a top surface of the redistribution layer and on side surfaces of the PIC chip, the buffer chip, the EIC chip, and the plurality of stacked structures.

18. The semiconductor package of claim 17, wherein the PIC chip is on the redistribution layer so that an active surface of the PIC chip faces upward, and
wherein the EIC chip is on the PIC chip so that an active surface of the EIC chip faces downward.

19. The semiconductor package of claim 17, wherein a thickness of the PIC chip is equal to a thickness of the buffer chip, and
wherein a thickness of the EIC chip is equal to a thickness of each of the plurality of stacked structures.

20. The semiconductor package of claim 17, wherein the molding layer comprises a first molding layer positioned on the redistribution layer and a second molding layer positioned on the first molding layer, wherein a top surface of the first molding layer, a top surface of the PIC chip, and a top surface of the buffer chip are coplanar, and
wherein a top surface of the second molding layer, a top surface of the EIC chip, and a top surface of each of the plurality of stacked structures are coplanar.
